(19) United States
(12) Patent Application Publication
(10) Pub. No.: US 2008/0297219 A1
(43) Pub. Date: Dec. 4, 2008

(54) EQUAL DELAY FLIP-FLOP BASED ON LOCALIZED FEEDBACK PATHS

(76) Inventors: SUJAN MANOHAR, Kundapur (IN); Pavan Vithal Torvi, Bangalore (IN)

Correspondence Address: Wade James Brady III;Texas Instruments Incorporated, P.O. Box 655474, M/S 3999, Dallas, TX, 75265, US

(21) Appl. No.: 12/107,789

(22) Filed: Apr. 23, 2008

Related U.S. Application Data
(60) Provisional application No. 60/940,726, filed on May 30, 2007.

(51) Int. Cl. H03K 3/289

(52) U.S. Cl. 327/202

(57) ABSTRACT

Equal delay flip-flop systems and complementary input complementary output equal delay flip-flop circuits are disclosed. In one embodiment, an equal delay flip-flop system includes a first delay flip-flop for processing a first input, including a first tri-state input driver for driving the first input, a first master latch for sampling and/or forwarding the first input, a first transmission gate for relaying the first input forwarded by the first master latch, and a first slave latch for storing and/or forwarding the first input. The equal delay flip-flop system further includes a second delay flip-flop for processing a second input, including a second tri-state input driver for driving the second input, a second master latch for sampling and/or forwarding the second input, a second transmission gate for relaying the second input forwarded by the second master latch, and a second slave latch for storing and/or forwarding the second input.

### RELATED APPLICATIONS

Benefit is claimed under 35 U.S.C. § 119(e) of any U.S. provisional applications Ser. No. 60/940,726 entitled “Complementary Input Complementary Output Equal Delay Flip-Flop” by Texas Instrument Inc., filed on May 30, 2007, which is herein incorporated in its entirety by reference for all purposes.

### FIELD OF TECHNOLOGY

Embodiments of the present invention relate to the field of electronics. More particularly, embodiments of the present invention relate to a flip-flop.

### BACKGROUND

With the advancement in electronic technology, microelectronic systems, devices or circuits are getting aggressively scaled. This may have resulted in variability and/or mismatches in the products. Such defects can make some parts of the microelectronic systems, devices or circuits operate faster than they are expected, whereas their other parts may operate slower, thus causing functional failures in the systems, devices or circuits.

FIG. 1 illustrates a conventional complementary input complementary output equal delay flip-flop 100. In FIG. 1, the first leg of the flip-flop 100 includes a tri-state input driver 106, a master latch inverter 110, a transmission gate 114 and a slave latch inverter 118. In addition, the second leg of the flip-flop 100 includes a tri-state input driver 108, a master latch inverter 112, a transmission gate 116 and a slave latch inverter 120. Furthermore, a transmission gate 122 provides a feedback path for the master latch inverter 110, while a transmission gate 124 provides a feedback path for the master latch inverter 112. In addition, a transmission gate 126 provides a feedback path for the slave latch inverter 118, while a transmission gate 128 provides a feedback path for the slave latch inverter 120.

Accordingly, when the clock (e.g., clk 130A) of the flip-flop 100 goes low, the transmission gate 122 and the transmission gate 124 are expected to turn off completely, and the master latches associated with the master latch inverter 110 and the master latch inverter 112 sample input 102 and input 104, respectively, where the input 104 is complementary to the input 102. In this state, the slave latches associated with the slave latch inverter 118 and the slave latch inverter 120 store (e.g., hold) old data. If the clock 130A of the flip-flop 100 goes high (i.e., complementary clock X 130B goes low), the transmission gate 126 and the transmission gate 128 are expected to turn off completely, and the master latches associated with the master latch inverter 110 and the master latch inverter 112 forward the sampled data as output 132 and output 134, respectively, where the output 134 is complementary to the output 132.

The complementary input complementary output equal delay flip-flop 100 may perform as expected if there is no overlap between the high and low clock pulses applied to respected components of the flip-flop 100. However, the variability and/or mismatches in the component design may result in unexpected overlaps in the clock pulses. As a result, during the transition of the clock pulses, a condition may arise where none of the transmission gates (e.g., 114, 116, 122, 124, 126 and 128) is completely turned-off, thus creating a feedback path 136 and feedback path 138 as illustrated in FIG. 1. In addition, the slave latch inverter 118 and the slave latch inverter 120, being strong output drivers, may cause the flip-flop 100 to write the old data that were stored in the slave latches back to the master latches, thereby resulting in loss of data at the output 132 as well as at the output 134. Furthermore, the write-back of the data can cause robustness failures, where the flip-flops latch new data at the negative edge of clock (e.g., which is considered as failure).

### SUMMARY

An equal delay flip-flop based on localized feedback paths is disclosed. In one aspect, an equal delay flip-flop system includes a first delay flip-flop for processing a first input and a second delay flip-flop for processing a second input. The first delay flip-flop further includes a first tri-state input driver for driving the first input, a first master latch for sampling or forwarding the first input, a first transmission gate for relaying the first input forwarded by the first master latch, and a first slave latch for storing or forwarding the first input. The second delay flip-flop includes a second tri-state input driver for driving the second input, a second master latch for sampling or forwarding the second input, a second transmission gate for relaying the second input forwarded by the second master latch, and a second slave latch for storing or forwarding the second input.

For example, the second input is complementary to the first input. The first delay flip-flop and the second delay flip-flop generate an equal delay of the first input and the second input, respectively. Also, a feedback path to each of the first master latch, the first slave latch, the second master latch, and the second slave latch is isolated from each other.

In another aspect, a complementary input complementary output equal delay flip-flop includes a first delay flip-flop for processing a first input. The first delay flip-flop includes a first tri-state input driver for driving the first input, a first master latch for sampling or forwarding the first input, a first transmission gate for relaying the first input forwarded by the first master latch, and a first slave latch for storing or forwarding the first input. The complementary input complementary output equal delay flip-flop also includes a second delay flip-flop for processing a second input. The second delay flip-flop includes a second tri-state input driver for driving the second input, a second master latch for sampling and/or forwarding the second input, a second transmission gate for relaying the second input forwarded by the second master latch, and a second slave latch for storing and/or forwarding the second input. For example, the second input is complementary to the first input.

The master latch includes a first feedback inverter coupled to a first forward inverter for forming a feedback path to the first forward inverter, the first slave latch includes a second feedback inverter coupled to a second forward inverter for forming a feedback path to the second forward inverter, the second master latch includes a third feedback inverter coupled to a third forward inverter for forming a feedback path to the third forward inverter, and the second slave latch includes a fourth feedback inverter coupled to a fourth forward inverter for forming a feedback path to the fourth forward inverter.

In yet another aspect, an equal delay flip-flop circuit includes a first delay flip-flop for processing a first input. The first delay flip-flop includes a first tri-state input driver for driving the first input, including a first PMOS, a second PMOS, a first NMOS and a second NMOS coupled in series. The first delay flip-flop further includes a first master latch for sampling and/or forwarding the first input, including a first forward inverter (e.g., includes a third NMOS and a third PMOS) and a first feedback inverter (e.g., includes a fourth NMOS and a fourth PMOS). The first delay flip-flop also includes a first transmission gate for relaying the first input forwarded by the first master latch, including a fifth NMOS and a fifth PMOS. In addition, the first delay flip-flop includes a first slave latch for storing and/or forwarding the first input, including a second forward inverter (e.g., includes a sixth NMOS and a sixth PMOS) and a second feedback inverter (e.g., includes a seventh NMOS and a seventh PMOS).

The equal delay flip-flop circuit also includes a second delay flip-flop for processing a second input. The second delay flip-flop includes a second tri-state input driver for driving the second input, including an eighth PMOS, a ninth PMOS, an eighth NMOS and a ninth NMOS coupled in series. The second delay flip-flop also includes a second master latch for sampling and/or forwarding the second input, including a third forward inverter (e.g., includes a tenth NMOS and a tenth PMOS) and a third feedback inverter (e.g., includes a eleventh NMOS and a eleventh PMOS). The second delay flip-flop further includes a second transmission gate for relaying the second input forwarded by the second master latch, including a twelfth NMOS and a twelfth PMOS. In addition, the second delay flip-flop includes a second slave latch for storing and/or forwarding the second input, including a fourth forward inverter (e.g., includes a thirteenth NMOS and a thirteenth PMOS) and a fourth feedback inverter (e.g., includes a fourteenth NMOS and a fourteenth PMOS).

For example, the second input is complementary to the first input. The first delay flip-flop and the second delay flip-flop generate an equal delay of the first input and the second input, respectively. Also, a feedback path to each of the first master latch, the first slave latch, the second master latch and the second slave latch is isolated from each other.

The methods, systems, and apparatuses disclosed herein may be implemented in any means for achieving various aspects. Other features will be apparent from the accompanying drawings and from the detailed description that follows.

### BRIEF DESCRIPTION OF THE DRAWINGS

Example embodiments are illustrated by way of example and not limitation in the figures of the accompanying drawings, in which like references indicate similar elements and in which:

FIG. 1 is a schematic diagram illustrating a conventional complementary input complementary output equal delay flip-flop.

FIG. 2 is a schematic diagram illustrating an exemplary equal delay flip-flop system based on localized feedback paths, according to one embodiment.

FIG. 3 is a schematic diagram illustrating operation of the equal delay flip-flop system in FIG. 2 during the low clock state, according to one embodiment.

FIG. 4 is a schematic diagram illustrating operation of the equal delay flip-flop system in FIG. 2 during the high clock state, according to one embodiment.

FIG. 5 is a schematic diagram of an exemplary complementary input complementary output flip-flop circuit based on localized feedback paths, according to one embodiment.

Other features of the present embodiments will be apparent from the accompanying drawings and from the detailed description that follows.

### DETAILED DESCRIPTION

An equal delay flip-flop based on localized feedback paths is disclosed. In the following detailed description of the embodiments of the invention, reference is made to the accompanying drawings that form a part hereof, and in which are shown by way of illustration specific embodiments in which the invention may be practiced. These embodiments are described in sufficient detail to enable those skilled in the art to practice the invention, and it is to be understood that other embodiments may be utilized and that changes may be made without departing from the scope of the present invention. The following detailed description is, therefore, not to be taken in a limiting sense, and the scope of the present invention is defined only by the appended claims.

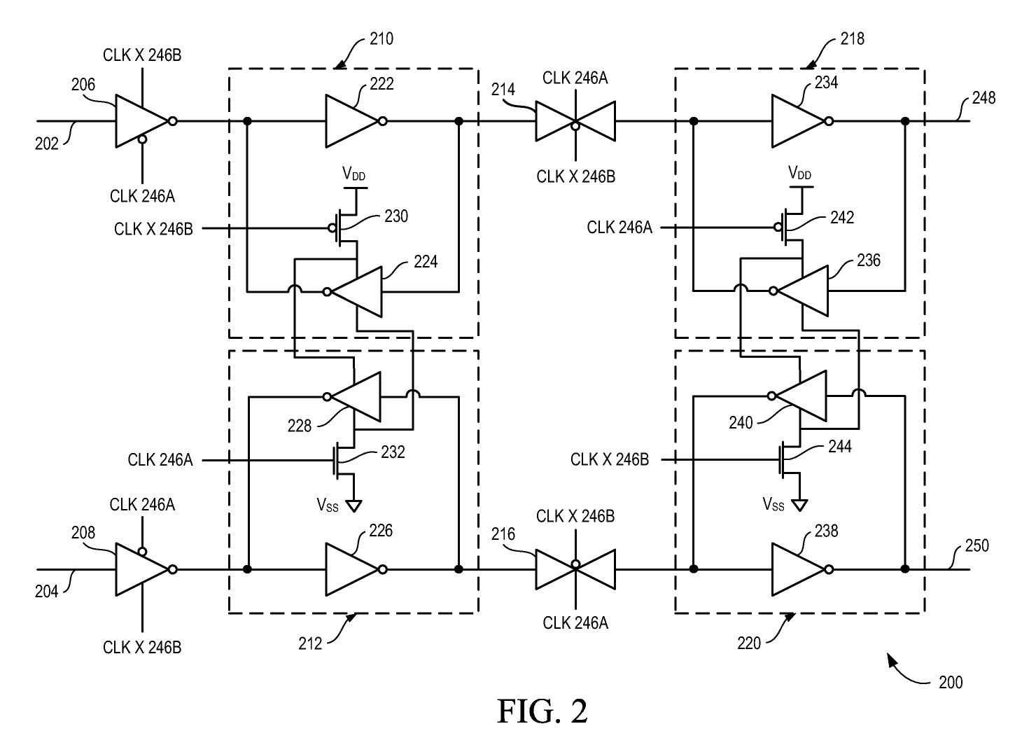

FIG. 2 is a schematic diagram illustrating an exemplary equal delay flip-flop system 200 based on localized feedback paths, according to one embodiment. In one embodiment, the system 200 (e.g., a complementary input complementary output equal delay flip-flop) includes a first delay flip-flop and a second delay flip-flop. As shown in FIG. 2, the first delay flip-flop includes a first tri-state input driver 206, a first master latch 210, a first transmission gate 214, and a first slave latch 218 to process a first input 202. Further, the second delay flip-flop includes a second tri-state input driver 208, a second master latch 212, a second transmission gate 216, and a second slave latch 220 to process a second input 204. In one embodiment, the second input 204 is complementary to the first input 202.

It is appreciated that, the first tri-state input driver 206 coupled to the first master latch 210, drives the first input 202. In one exemplary implementation, the first master latch 210 samples and/or forwards the first input 202 to the first transmission gate 214. In one embodiment, the first master latch 210 includes a first feedback inverter 224 coupled to a first forward inverter 222 for forming the feedback path to the first forward inverter 222.

Further, the first transmission gate 214 coupled to the first slave latch 218 relays the first input 202 forwarded by the first master latch 210. In one embodiment, the first slave latch 218 stores and/or forwards the first input 202. In one example embodiment, the first slave latch 218 includes a second feedback inverter 236 coupled to a second forward inverter 234 for forming the feedback path to the second forward inverter 234. In one exemplary implementation, the first slave latch 218 generates a first output 248 of the first delay flip-flop.

It is appreciated that the second tri-state input driver 208 coupled to the second master latch 212, drives the second input 204. Then, the second master latch 212 samples and/or forwards the second input 204 to the second transmission gate 216. In one embodiment, the second master latch 212 includes a third feedback inverter 228 coupled to a third forward inverter 226 for forming the feedback path to the third forward inverter 226.

Further, the second transmission gate 216 coupled to the second slave latch 220, relays the second input 204 forwarded by the master latch 212. The second slave latch 220 stores and/or forwards the second input 204. In one embodiment, the second slave latch 220 includes a fourth feedback inverter 240 coupled to a fourth forward inverter 238 for forming the feedback path to the fourth forward inverter 238. In one exemplary implementation, the second slave latch 220 generates a second output 250 of the second delay flip-flop. It is appreciated that, the first delay flip-flop and the second delay flip-flop generate an equal delay of the first input 202 and the second input 204, respectively.

In the example embodiment illustrated in FIG. 2, a feedback path to each of the first master latch 210, the first slave latch 218, the second master latch 212 and the second slave latch 220 is isolated from each other. Also, the first tri-state input driver 206, the first feedback inverter 224, the first transmission gate 214, the second feedback inverter 236, the second tri-state input driver 208, the third feedback inverter 228, the second transmission gate 216, the fourth feedback inverter 240 are controlled by a clock (e.g., clk 246A). As shown in FIG. 2, each of the first feedback inverter 224, the second feedback inverter 236, the third feedback inverter 228 and the fourth feedback inverter 240 is coupled to a clock transistor (e.g., clock transistor 230, 242, 232 and 244, respectively). In one example embodiment, each clock transistor (e.g., 230, 242, 232 or 244) is controlled by the clock 246A (e.g., or its complementary clock (e.g., clk X 246B).

In one embodiment, a driving power of each of the first feedback inverter 224, the second feedback inverter 236, the third feedback inverter 228 and the fourth feedback inverter 240 is less than a driving power of each of the first forward inverter 222, the second forward inverter 234, the third forward inverter 226 and the fourth forward inverter 238, respectively. This can prevent data driven by the feedback inverter(s) from competing with data driven by the forward inverter(s) during transitioning of the clock 246A.

In one exemplary implementation, the driving power is controlled by scaling the first feedback inverter 224, the second feedback inverter 236, the third feedback inverter 228, the fourth feedback inverter 240, the first forward inverter 222, the second forward inverter 234, the third forward inverter 226 or the fourth forward inverter 238. It is appreciated that, the number of clock transistors driven by the clock signal (e.g., clock 246A and clock X 246B) is reduced, thereby resulting in lower clock power. In one embodiment, a size of the clock transistors 230, 242, 232 or 244 is scaled to reduce clock pin capacitance, seen by the clock 246A, where the clock pin capacitance is an amount of capacitance a clock (e.g., the clock 246A) has to drive.

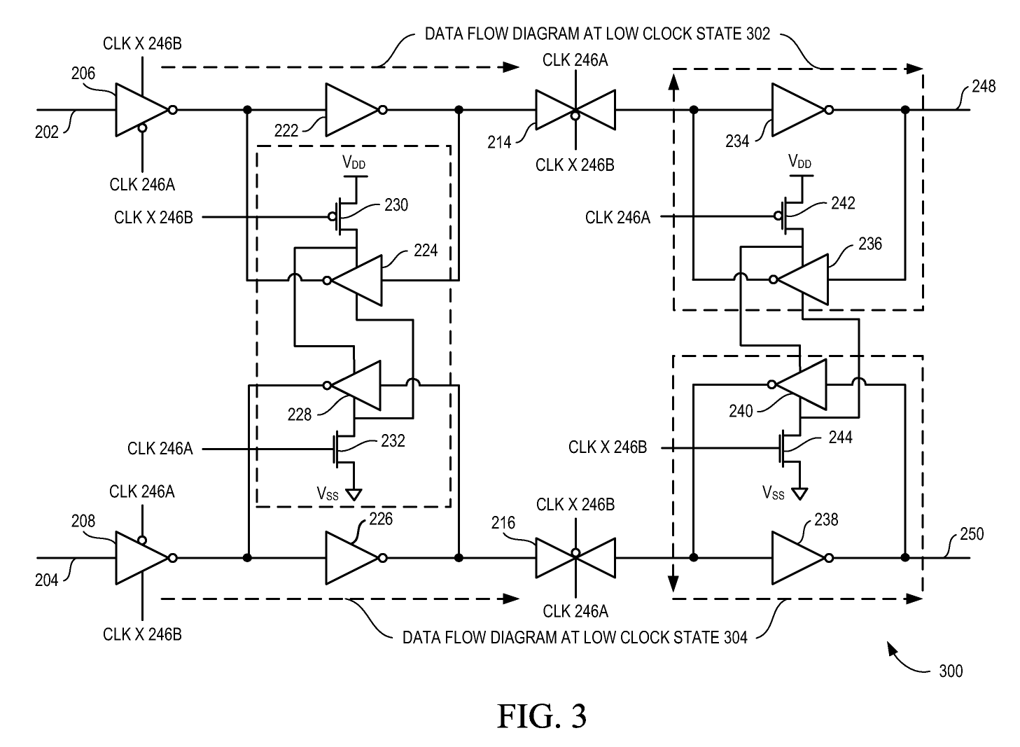

FIG. 3 is a schematic diagram 300 illustrating operation of the equal delay flip-flop system 200 in FIG. 2, during the low clock state, according to one embodiment. Particularly, FIG. 3 illustrates data flow lines 302 and 304 in the two legs of the equal delay flip-flop system 200, during the low clock state (i.e., when the clock 246A is low). When the clock 246A is low, the first feedback inverter 224, the third feedback inverter 228, the first transmission gate 214 and the second transmission gate 216 are turned off. In one exemplary implementation, the first input 202 and the second input 204 are sampled (e.g., by the first master latch 210 and the second master latch 212, respectively) if the clock 246A is low.

In the example embodiment illustrated in FIG. 3, when the clock 246A goes low, the second feedback inverter 236 and the fourth feedback inverter 240 are turned on, and the first feedback inverter 224 and the third feedback inverter 228 are turned off completely. In addition, the first master latch 210 associated with the first forward inverter 222 samples the first input 202, and the second master latch 212 associated with the third forward inverter 226 samples the second input 204. In this state (i.e., when clock 246A is 0), the old data is looped/stored in the first slave latch 218 and the second slave latch 220 since the second feedback inverter 236 and the fourth feedback inverter 240 are turned on. It is appreciated that the first output 248 and the second output 250 are driven by a value that is stored in the first slave latch 218 and the second slave latch 220.

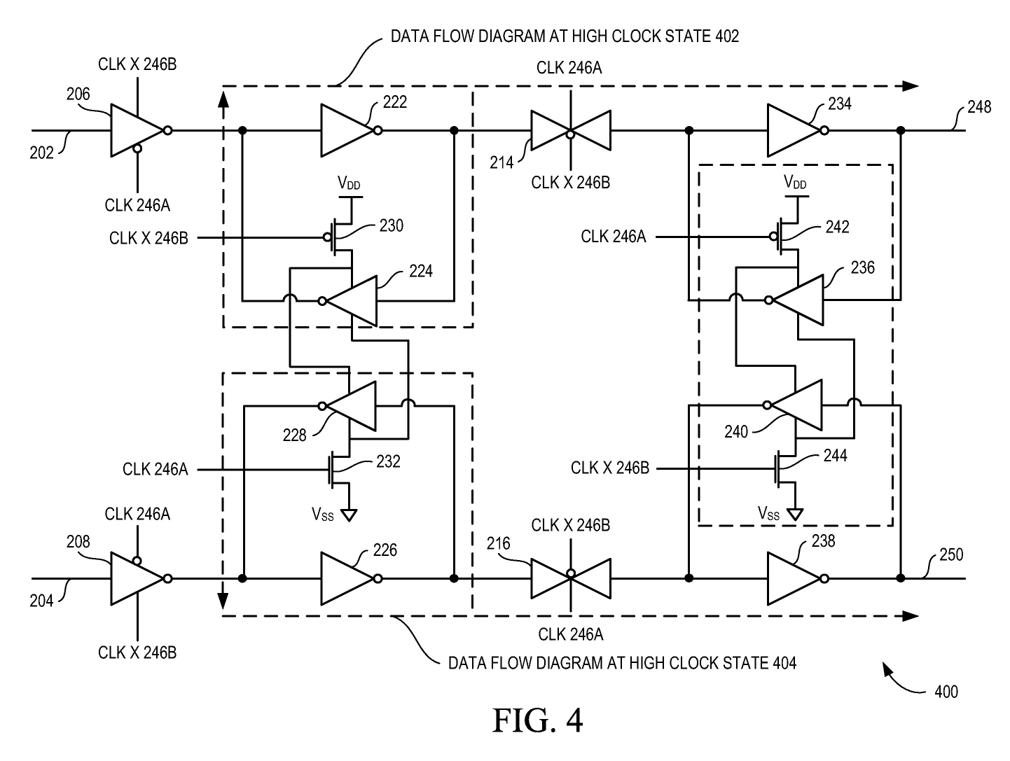

FIG. 4 is a schematic diagram 400 illustrating operation of the equal delay flip-flop system 200 in FIG. 2 during the high clock state, according to one embodiment. Particularly, FIG. 4 illustrates data flow lines 402 and 404 in the two legs of the equal delay flip-flop system 200, during the high clock state (i.e., when the clock 246A is high). When the clock 246A is high, the second feedback inverter 236 and the fourth feedback inverter 240 are turned off. In one exemplary implementation, the first output 248 and the second output 250 are forwarded by the first forward inverter 222 and the third forward inverter 226, respectively, if the clock 246A is high.

In the example embodiment illustrated in FIG. 4, when the clock 246A goes high, the first feedback inverter 224 and the third feedback inverter 228 are turned on, and the second feedback inverter 236 and the fourth feedback inverter 240 are turned off completely. In addition, the first master latch 210 associated with the first forward inverter 222 and the second master latch 212 associated with the third forward inverter 226 forward the sampled data (e.g., the data sampled when the clock 246A was low) as the first output 248 and the second output 250 respectively. In one example embodiment, the second output 250 is complementary to the first output 248.

In one exemplary implementation, the first transmission gate 214 and the second transmission gate 216 are turned on when the clock is high. When the clock is high, the master loop is closed, and the data sampled by the first master latch 210 and/or the second master latch 212 is looped/stored in the first master latch 210 and the second master latch 212, respectively. In another embodiment, the data stored in the first master latch 210 and/or the second master latch 212 is forwarded to the first slave latch 218 and the second slave latch 220 through the first transmission gate 214 and the second transmission gate 216, respectively. Furthermore, the second forward inverter 234 and the fourth forward inverter 238 generate the first output 248 and the second output 250, respectively. The first output 248 and the second output 250 have an equal delay of the first input 202 and the second input 204, respectively.

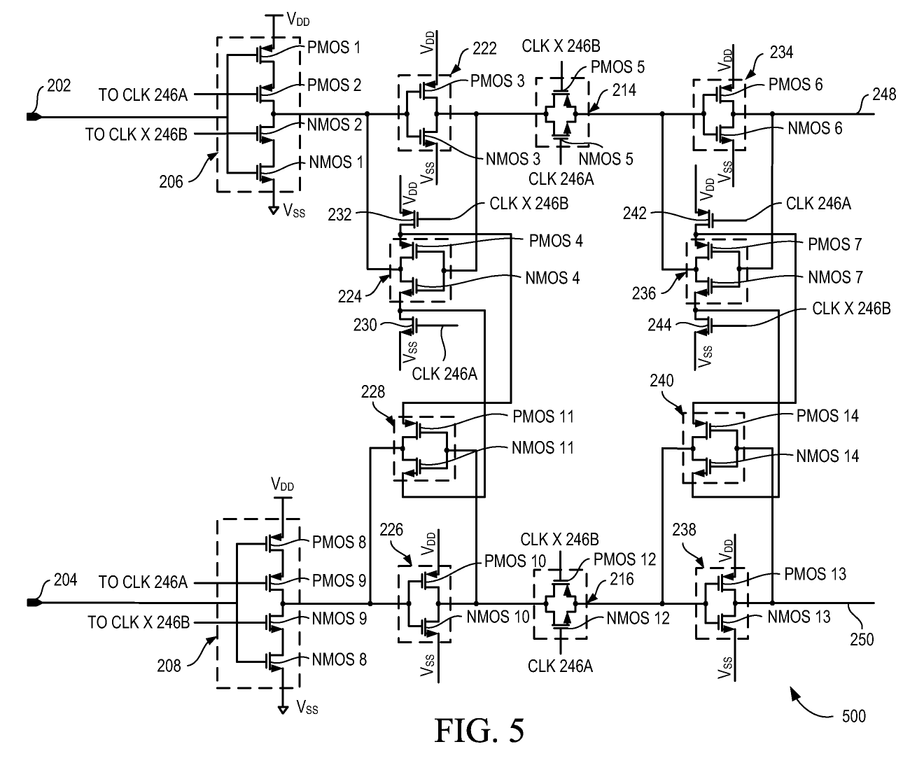

FIG. 5 is a schematic diagram of an exemplary complementary input complementary output flip-flop circuit 500 based on localized feedback paths, according to one embodiment. In one embodiment, the first leg of the circuit 500 includes the first tri-state input driver 206, the first master latch 210, the first transmission gate 214, and the first slave latch 218 to process the first input 202.

As shown in FIG. 5, the first tri-state input driver 206 for driving the first input 202 includes a first PMOS (PMOS 1), a second PMOS (PMOS 2), a first NMOS (NMOS 1) and a second NMOS (NMOS 2) coupled in series. The first master latch 210 for sampling and/or forwarding the first input 202 includes the first forward inverter 222 and the first feedback inverter 224. In one exemplary implementation, the first forward inverter 222 includes a third NMOS (NMOS 3) and a third PMOS (PMOS 3), and the first feedback inverter 224 includes a fourth NMOS (NMOS 4) and a fourth PMOS (PMOS 4).

Further, the transmission gate 214 for relaying the first input 202 forwarded by the first master latch 210, includes a fifth NMOS (NMOS 5) and a fifth PMOS (PMOS 5). In addition, the first slave latch 218 for storing and/or forwarding the first input 202, includes the second forward inverter 234 and the second feedback inverter 236. In one exemplary implementation, the second forward inverter 234 includes a sixth NMOS (NMOS 6) and a sixth PMOS (PMOS 6), and the second feedback inverter 236 includes a seventh NMOS (NMOS 7) and a seventh PMOS (PMOS 7).

In one embodiment, the second leg of the circuit 500 includes the second tri-state input driver 208, the second master latch 212, the second transmission gate 216, and the second slave latch 220 to process the second input 204. Further, the second tri-state input driver 208 for driving the second input 204 includes an eighth PMOS (PMOS 8), a ninth PMOS (PMOS 9), an eighth NMOS (NMOS 8) and a ninth NMOS (NMOS 9) coupled in series.

The second master latch 212 for sampling and/or forwarding the second input 204 includes the third forward inverter 226 and the third feedback inverter 228. In one exemplary implementation, the third forward inverter 226 includes a tenth NMOS (NMOS 10) and a tenth PMOS (PMOS 10), and the third feedback inverter 228 includes an eleventh NMOS (NMOS 11) and an eleventh PMOS (PMOS 11).

Further, the second transmission gate 216 for relaying the second input 204 forwarded by the second master latch 212, includes a twelfth NMOS (NMOS 12) and a twelfth PMOS (PMOS 12). In addition, the second slave latch 220 for storing and/or forwarding the second input 204 includes the fourth forward inverter 238 and the fourth feedback inverter 240. In one exemplary implementation, the fourth forward inverter 238 includes a thirteenth NMOS (NMOS 13) and a thirteenth PMOS (PMOS 13), and the fourth feedback inverter 240 includes a fourteenth NMOS (NMOS 14) and a fourteenth PMOS (PMOS 14).

As illustrated above, the second input 204 is complementary to the input 202. Further, the feedback path to each of the first master latch 210, the first slave latch 218, the second master latch 212 and the second slave latch 220 is isolated from each other. It is appreciated that, the first leg and the second leg of the circuit 500 generate an equal delay of the first input 202 and the second input 204, respectively.

In the example embodiment illustrated in FIG. 5, the first tri-state input driver 206, the first feedback inverter 224, the first transmission gate 214, the third feedback inverter 228, the second tri-state input driver 208, the second feedback inverter 236, the second transmission gate 216, and the fourth feedback inverter 240 are controlled by the clock 246A. Furthermore, each of the first feedback inverter 224, the second feedback inverter 236, the third feedback inverter 228 and the fourth feedback inverter 240 is coupled to the clock transistor 230, 242, 232 and 244 respectively.

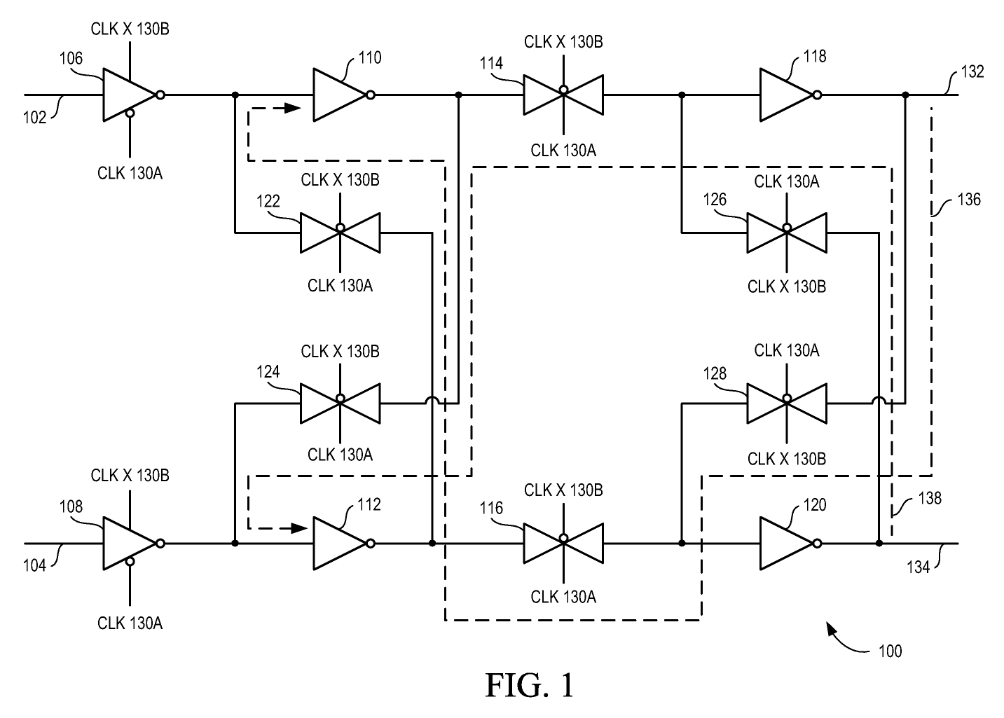

In one embodiment, each of localized feedback paths realized by the first feedback inverter 224, the second feedback inverter 236, the third feedback inverter 228, and/or the fourth feedback inverter 240 as illustrated in FIG. 2 through 5 prevents the data write-back due to imperfect clock transitioning as discussed in FIG. 1.

In one embodiment, since the forward inverters are different from the feedback inverters, the equal delay flip-flop system 200 and/or the complementary input complementary output flip-flop circuit 500 provides flexibility to independently size the forward inverters and the feedback inverters, resulting in improved performance and increased robustness. In one exemplary implementation, the robustness of the equal delay flip-flop system 200 and/or the complementary input complementary output flip-flop circuit 500 may be robust despite bad clock slew, very fast data slew, and/or highest allowed library operating voltage. Also, in one embodiment, the equal delay flip-flop system 200 and/or the complementary input complementary output flip-flop circuit 500 includes less number of clock transistors which results in lower clock power. Furthermore, since the critical paths having transistors that are controlled by the clock 246A are less in number, the transistors can be sized down, resulting in further reduction in the clock pin capacitance.

Although the present embodiments have been described with reference to specific example embodiments, it will be evident that various modifications and changes may be made to these embodiments without departing from the broader spirit and scope of the various embodiments. For example, the various devices, modules, analyzers, generators, etc. described herein may be enabled and operated using hardware circuitry (e.g., CMOS based logic circuitry), firmware, software and/or any combination of hardware, firmware, and/or software (e.g., embodied in a machine readable medium). For example, the various electrical structure and methods may be embodied using transistors, logic gates, and electrical circuits (e.g., application specific integrated circuitry (ASIC)).

What is claimed is:

1. An equal delay flip-flop system, comprising:
a first delay flip-flop for processing a first input, comprising:
a first tri-state input driver for driving the first input;
a first master latch for sampling or forwarding the first input;
a first transmission gate for relaying the first input forwarded by the first master latch; and
a first slave latch for storing or forwarding the first input; and
a second delay flip-flop for processing a second input, comprising:
a second tri-state input driver for driving the second input;
a second master latch for sampling or forwarding the second input;
a second transmission gate for relaying the second input forwarded by the second master latch; and
a second slave latch for storing or forwarding the second input,
wherein the second input is complementary to the first input, wherein the first delay flip-flop and the second delay flip-flop generate an equal delay of the first input and the second input, respectively, and wherein a feedback path to each of the first master latch, the first slave latch, the second master latch and the second slave latch is isolated from each other.

2. The system of claim 1, wherein the first master latch comprises a first feedback inverter coupled to a first forward inverter for forming the feedback path to the first forward inverter, and wherein the first slave latch comprises a second feedback inverter coupled to a second forward inverter for forming the feedback path to the second forward inverter.

3. The system of claim 2, wherein the second master latch comprises a third feedback inverter coupled to a third forward inverter for forming the feedback path to the third forward inverter, and wherein the second slave latch comprises a fourth feedback inverter coupled to a fourth forward inverter for forming the feedback path to the fourth forward inverter.

4. The system of claim 3, wherein the first tri-state input driver, the first feedback inverter, the first transmission gate, the second feedback inverter, the second tri-state input driver, the third feedback inverter, the second transmission gate, and the fourth feedback inverter are controlled by a clock.

5. The system of claim 4, wherein a driving power of each of the first feedback inverter, the second feedback inverter, the third feedback inverter and the fourth feedback inverter is less than a driving power of each of the first forward inverter, the second forward inverter, the third forward inverter and the fourth forward inverter, respectively.

6. The system of claim 5, wherein the driving power is controlled by scaling the first feedback inverter, the second feedback inverter, the third feedback inverter, the fourth feedback inverter, the first forward inverter, the second forward inverter, the third forward inverter or the fourth forward inverter.

7. The system of claim 4, wherein the first feedback inverter, the third feedback inverter, the first transmission gate and the second transmission gate are turned off if the clock is low.

8. The system of claim 7, wherein the first input and the second input are sampled if the clock is low.

9. The system of claim 4, wherein the second feedback inverter and the fourth feedback inverter are turned off if the clock is high.

10. The system of claim 9, wherein a first output and a second output are forwarded by the first forward inverter and the third forward inverter, respectively, if the clock is high.

11. The system of claim 4, wherein the first tri-state input driver or the second tri-state input driver comprises two PMOSes in series serially coupled with two NMOSes in series.

12. The system of claim 4, wherein the first forward inverter, the first feedback inverter, the second forward inverter, the second feedback inverter, the third forward inverter, the third feedback inverter, the fourth forward inverter or the fourth feedback inverter comprises a PMOS coupled in series with a NMOS.

13. The system of claim 4, wherein each of the first feedback inverter, the second feedback inverter, the third feedback inverter and a fourth feedback inverter is coupled to a clock transistor.

14. The system of claim 13, wherein a size of the clock transistor is scaled to reduce clock pin capacitance seen by the clock.

15. A complementary input complementary output equal delay flip-flop, comprising:
a first delay flip-flop for processing a first input, comprising:
a first tri-state input driver for driving the first input;
a first master latch for sampling or forwarding the first input;
a first transmission gate for relaying the first input forwarded by the first master latch; and
a first slave latch for storing or forwarding the first input; and
a second delay flip-flop for processing a second input, comprising:
a second tri-state input driver for driving the second input;
a second master latch for sampling or forwarding the second input;
a second transmission gate for relaying the second input forwarded by the second master latch; and
a second slave latch for storing or forwarding the second input,
wherein the second input is complementary to the first input, wherein the first master latch comprises a first feedback inverter coupled to a first forward inverter for forming a feedback path to the first forward inverter, wherein the first slave latch comprises a second feedback inverter coupled to a second forward inverter for forming a feedback path to the second forward inverter, wherein the second master latch comprises a third feedback inverter coupled to a third forward inverter for forming a feedback path to the third forward inverter, and wherein the second slave latch comprises a fourth feedback inverter coupled to a fourth forward inverter for forming a feedback path to the fourth forward inverter.

16. The flip-flop of claim 15, wherein the first tri-state input driver, the first feedback inverter, the first transmission gate, the second feedback inverter, the second tri-state input driver, the third feedback inverter, the second transmission gate, and the fourth feedback inverter are controlled by a clock.

17. The flip-flop of claim 15, wherein a driving power of each of the first feedback inverter, the second feedback inverter, the third feedback inverter and the fourth feedback inverter is less than a driving power of each of the first forward inverter, the second forward inverter, the third forward inverter and the fourth forward inverter, respectively.

18. The flip-flop of claim 15, wherein each of the first feedback inverter, the second feedback inverter, the third feedback inverter and a fourth feedback inverter is coupled to a clock transistor.

19. An equal delay flip-flop circuit, comprising:
a first delay flip-flop for processing a first input, comprising:
a first tri-state input driver for driving the first input, comprising a first PMOS, a second PMOS, a first NMOS and a second NMOS coupled in series;
a first master latch for sampling or forwarding the first input, comprising:
a first forward inverter comprising a third NMOS and a third PMOS; and
a first feedback inverter comprising a fourth NMOS and a fourth PMOS;
a first transmission gate for relaying the first input forwarded by the first master latch, comprising a fifth NMOS and a fifth PMOS; and
a first slave latch for storing or forwarding the first input, comprising:
a second forward inverter comprising a sixth NMOS and a sixth PMOS; and
a second feedback inverter comprising a seventh NMOS and a seventh PMOS; and
a second delay flip-flop for processing a second input, comprising:
a second tri-state input driver for driving the second input, comprising an eighth PMOS, a ninth PMOS, an eighth NMOS and a ninth NMOS coupled in series;
a second master latch for sampling or forwarding the second input, comprising:
a third forward inverter comprising a tenth NMOS and a tenth PMOS; and
a third feedback inverter comprising an eleventh NMOS and an eleventh PMOS;
a second transmission gate for relaying the second input forwarded by the second master latch, comprising a twelfth NMOS and a twelfth PMOS; and
a second slave latch for storing or forwarding the second input, comprising:
a fourth forward inverter comprising a thirteenth NMOS and a thirteenth PMOS; and
a fourth feedback inverter comprising a fourteenth NMOS and a fourteenth PMOS,
wherein the second input is complementary to the first input, wherein the first delay flip-flop and the second delay flip-flop generate an equal delay of the first input and the second input, respectively, and wherein a feedback path to each of the first master latch, the first slave latch, the second master latch and the second slave latch is isolated from each other.

20. The circuit of claim 19, wherein the first tri-state input driver, the first feedback inverter, the first transmission gate, the third feedback inverter, the second tri-state input driver, the second feedback inverter, the second transmission gate, and the fourth feedback inverter are controlled by a clock.
